(19) United States
(12) Patent Application Publication
(10) Pub. No.: US 2011/0233689 A1
(43) Pub. Date: Sep. 29, 2011

(54) SEMICONDUCTOR DEVICE, PROCESS FOR PRODUCING SEMICONDUCTOR DEVICE, SEMICONDUCTOR SUBSTRATE, AND PROCESS FOR PRODUCING SEMICONDUCTOR SUBSTRATE

(75) Inventors: Masahiko Hata, Ibaraki (JP); Noboru Fukuhara, Ibaraki (JP); Hisashi Yamada, Ibaraki (JP); Shinichi Takagi, Tokyo (JP); Masakazu Sugiyama, Tokyo (JP); Mitsuru Takenaka, Tokyo (JP); Tetsuji Yasuda, Ibaraki (JP); Noriyuki Miyata, Ibaraki (JP); Taro Itatani, Ibaraki (JP); Hiroyuki Ishii, Ibaraki (JP); Akihiro Ohtake, Ibaraki (JP); Jun Nara, Ibaraki (JP)

(73) Assignees: SUMITOMO CHEMICAL COMPANY, LIMITED, Chuo-ku, Tokyo (JP); THE UNIVERSITY OF TOKYO, Bunkyo-ku, Tokyo (JP); NATIONAL INSTITUTE FOR MATERIALS SCIENCE, Tsukuba-shi, Ibaraki (JP)

(21) Appl. No.: 13/133,092

(22) PCT Filed: Nov. 27, 2009
(86) PCT No.: PCT/JP2009/006426

§ 371 Date: Jun. 6, 2011

(30) Foreign Application Priority Data
Dec. 8, 2008 (JP) 2008-312761

(51) Int. Cl. H01L 29/78; H01L 29/04; H01L 21/336; H01L 29/20; H01L 21/20

(52) U.S. Cl. 257/411; 257/288; 438/287; 257/615; 438/478; 257/E29.242; 257/E29.004; 257/E29.089; 257/E21.409; 257/E21.09

(57) ABSTRACT

There is provided a semiconductor device that includes a III-V Group compound semiconductor having a zinc-blende-type crystal structure, an insulating material being in contact with the (111) plane of the III-V Group compound semiconductor, a plane of the III-V Group compound semiconductor equivalent to the (111) plane, or a plane that has an off angle with respect to the (111) plane or the plane equivalent to the (111) plane, and an MIS-type electrode being in contact with the insulating material and including a metal conductive material.

### TECHNICAL FIELD

The present invention relates to a semiconductor device, a method of manufacturing the same, a semiconductor wafer and a method of manufacturing the same. This patent application is made from the research and development entrusted by the Ministry of Economy, Trade and Industry and awarded in 2008 as “strategic technology development (in the field of nanoelectronics semiconductor new material/structure development—new material/structure nanoelectronics device [(4) development of III-V MISFET/III-V-On-Insulator (III-V-OI) MISFET fabrication process technology-characteristics evaluation of integrated structure and development of design factors]), and this patent application is subjected to the Industrial Technology Enhancement Act 19.

### BACKGROUND ART

In recent years, various highly-advanced electronic devices in which GaAs-based or other compound semiconductors are used for active regions have been developed. For example, metal-insulator-semiconductor (MIS)-type field-effect transistors (hereunder also referred to as MISFET) in which compound semiconductor is used for channel layers are expected to serve as switching devices appropriate for high-frequency operations and high-power operations. In the MISFETs using compound semiconductor for their channel regions, it is important to reduce interface states at the boundary between the compound semiconductor and an insulating material. For example, Non-patent Document 1 discloses that the interface states generated at the boundary can be reduced by treating a surface of the compound semiconductor with sulfide.

Non-Patent Document 1: S. Arabasz, et al., Vac. Vol. 80, 2006, p. 888

### SUMMARY OF THE INVENTION

### Problem to be Solved by the Invention

As described above, it has been recognized as an object that the interface states at the boundary should be reduced for practical use of the compound semiconductor MISFETs. However, factors affecting the interface states at the boundary were not revealed.

### MEANS FOR SOLVING PROBLEM

For a solution to the above-mentioned problems, according to the first aspect related to the present invention, provided is one exemplary semiconductor device. The semiconductor device includes a III-V Group compound semiconductor having a zinc-blende-type crystal structure; an insulating material being in contact with the (111) plane of the III-V Group compound semiconductor, a plane of the III-V Group compound semiconductor equivalent to the (111) plane, or a plane that has an off angle with respect to the (111) plane or the plane equivalent to the (111) plane; and an MIS-type electrode being in contact with the insulating material and including a metal conductive material. The insulating material can be in contact with the (111)A plane of the III-V Group compound semiconductor, a plane of the III-V Group compound semiconductor equivalent to the (111)A plane, or a plane having an off angle with respect to the (111)A plane or the plane equivalent to the (111)A plane. The semiconductor wafer, for example, further includes a wafer selected from the group consisting of a Si wafer, an SOI wafer and a GOI wafer, and the III-V Group compound semiconductor is disposed on a part of the wafer.

The semiconductor device further includes, for example, an MIS-type field effect transistor including the III-V Group compound semiconductor, the insulating material, the MIS-type electrode and a pair of input/output electrodes electrically connected to the III-V Group compound semiconductor. A channel layer of the MIS-type field effect transistor can include In_{z}Ga_{1-z}As_{z′}Sb_{1-z′} (where 0≦z≦1, 0≦z′≦1) or InₓGa₁₋ₓAs_{y}P_{1-y} (where 0≦x≦1, 0≦y≦1).

The insulating material includes, for example, at least one member selected from the group consisting of Al₂O₃, Ga₂O₃, La₂O₃, AlN, GaN, SiO₂, ZrO₂, HfO₂, HfₓSi₁₋ₓO_{y} (where 0≦x≦1, 1≦y≦2), HfₓAl₂₋ₓO_{y} (where 0≦x≦2, 1≦y≦3), Hf_{x′}Si_{1-x′}O_{y′}N_{2-y′} (where 0≦x′≦1, 1≦y′≦2) and Ga_{2-x″}Gd_{x″}O₃ (where 0≦x″≦2), or a layered structure thereof. The insulating material includes, for example, a III-V Group compound semiconductor containing Al and having a zinc-blende-type crystal structure, or an oxide of a III-V Group compound semiconductor containing Al and having a zinc-blende-type crystal structure. The metal conductive material includes, for example, at least one member selected from the group consisting of TaC, TaN, TiN, Ti, Au, W, Pt and Pd.

According to the second aspect related to the present invention, provided is one exemplary method of manufacturing a semiconductor device. The method includes a step of preparing a III-V Group compound semiconductor that has a zinc-blende-type crystal structure and that has the (111) plane, a plane equivalent to the (111) plane, or a plane having an off angle with respect to the (111) plane or the plane equivalent to the (111) plane; a step of forming an insulating material that is in contact with the (111) plane, the plane equivalent to the (111) plane, or the plane having an off angle with respect to the (111) plane or the plane equivalent to the (111) plane; and a step of forming an MIS-type electrode that is in contact with the insulating material and that is made of a metal conductive material. The insulating material can be in contact with the (111)A plane of the III-V Group compound semiconductor, a plane of the III-V Group compound semiconductor equivalent to the (111)A plane, or a plane having an off angle with respect to the (111)A plane or the plane equivalent to the (111)A plane.

The manufacturing method can further include a step of forming input/output electrodes electrically connected to the III-V Group compound semiconductor. The step of forming an MIS-type electrode is performed, for example, before the step of forming the input/output electrodes. The step of forming input/output electrodes can be performed before the step of forming the insulating material.

The insulating material is formed and obtained by, for example, an ALD method or a MOCVD method under an atmosphere containing a reducing material. The manufacturing method can further include a step of annealing the insulating material under vacuum or under an atmosphere containing hydrogen after the insulating material is formed. The step of preparing a III-V Group compound semiconductor can include a step of preparing any one wafer of a Si wafer, an SOI wafer and a GOI wafer; and a step of forming the III-V Group compound semiconductor on a part of the wafer.

According to the third aspect related to the present invention, provided is one exemplary semiconductor wafer in which a III-V Group compound semiconductor having a zinc-blende-type crystal structure has been placed. In the semiconductor wafer, the (111) plane of the III-V Group compound, a plane of the III-V Group compound semiconductor equivalent to the (111) plane, or a plane having an off angle with respect to the (111) plane or the plane equivalent to the (111) plane has been disposed in parallel to the main plane of the semiconductor wafer. The (111)A plane of the III-V Group compound semiconductor, a plane of the III-V Group compound semiconductor equivalent to the (111)A plane, or a plane having an off angle with respect to the (111)A plane or the plane equivalent to the (111)A plane can be disposed in parallel to the main plane of the semiconductor wafer. The semiconductor wafer can further include any one wafer of a Si wafer, an SOI wafer and a GOI wafer, and the III-V Group compound semiconductor can be disposed on a part of the wafer.

In the semiconductor wafer, the III-V Group compound semiconductor includes, for example, In_{z}Ga_{1-z}As_{z′}Sb_{1-z′} (where 0≦z≦1, 0≦z′≦1) or InₓGa₁₋ₓAs_{y}P_{1-y} (where 0≦x≦1, 0≦y≦1). The semiconductor wafer can further include an inhibition layer that inhibits crystal growth of the III-V Group compound semiconductor that occurs on a surface of a Si or Ge crystal layer of a surface of the wafer. An opening penetrating the inhibition layer to the Si or Ge crystal layer can be formed in the inhibition layer, and the III-V Group compound semiconductor can be formed inside the opening.

In the semiconductor wafer, the III-V Group compound semiconductor can include a seed compound semiconductor whose crystal has grown to have a convex shape protruding from a surface of the inhibition layer, and a lateral compound semiconductor having laterally grown along the inhibition layer with the seed compound semiconductor serving as a nucleus. The lateral compound semiconductor can include a first lateral compound semiconductor having laterally grown along the inhibition layer with the seed compound semiconductor serving as a nucleus; and a second lateral compound semiconductor whose crystal has laterally grown along the inhibition layer in a direction different from that of the first lateral compound semiconductor using the first lateral compound semiconductor as a nucleus. In the semiconductor wafer, the III-V Group compound semiconductor can further include an upper-layer compound semiconductor whose crystal has grown on the lateral compound semiconductor.

According to the fourth aspect related to the present invention, provided is one exemplary semiconductor wafer that includes: a III-V Group compound semiconductor having a zinc-blende-type crystal structure, and an insulating material being in contact with the (111) plane of the III-V Group compound semiconductor, a plane of the III-V Group compound semiconductor equivalent to the (111) plane, or a plane having an off angle with respect to the (111) plane or the plane equivalent to the (111) plane. For example, the insulating material is in contact with the (111)A plane of the III-V Group compound semiconductor, a plane of the III-V Group compound semiconductor equivalent to the (111)A plane, or a plane having an off angle with respect to the (111)A plane or the plane equivalent to the (111)A plane. The semiconductor wafer can further include any one wafer of a Si wafer, an SOI wafer and a GOI wafer, wherein the III-V Group compound semiconductor has been disposed on a part of the wafer.

The III-V Group compound semiconductor can include In_{z}Ga_{1-z}As_{z′}Sb_{1-z′} (where 0≦z≦1, 0≦z′≦1) or InₓGa₁₋ₓAs_{y}P_{1-y} (where 0≦x≦1, 0≦y≦1). The insulating material can include at least one member selected from the group consisting of Al₂O₃, Ga₂O₃, La₂O₃, AlN, GaN, SiO₂, ZrO₂, HfO₂, HfₓSi₁₋ₓO_{y} (where 0≦x≦1, 1≦y≦2), HfₓAl₂₋ₓO_{y} (where 0≦x≦2, 1≦y≦3), Hf_{x′}Si_{1-x′}O_{y′}N_{2-y′} (where 0≦x′≦1, 1≦y′≦2) and Ga_{2-x″}Gd_{x″}O₃ (where 0≦x″≦2), or a layered structure thereof.

The insulating material can include a III-V Group compound semiconductor containing Al and having a zinc-blende-type crystal structure, or an oxide of a III-V Group compound semiconductor containing Al and having a zinc-blende-type crystal structure.

According to the fifth aspect related to the present invention, provided is one exemplary method of manufacturing a semiconductor wafer that includes a III-V Group compound semiconductor. The method includes: a step of preparing a base wafer; a step of forming an inhibition layer that inhibits crystal growth of the III-V Group compound semiconductor on the base wafer; a step of forming, in the inhibition layer, an opening penetrating the inhibition layer to the base wafer; a step of growing, in the opening, a crystal of a seed compound semiconductor to make it have a convex shape protruding from a surface of the inhibition layer; a step of growing a crystal of a lateral compound semiconductor along the inhibition layer with the seed compound semiconductor serving as a nucleus; and a step of growing a crystal of an upper-layer compound semiconductor on the lateral compound semiconductor.

### BRIEF DESCRIPTION OF THE DRAWINGS

FIG. 1 schematically illustrates an exemplary cross section of a semiconductor device 110.

FIG. 2 schematically illustrates an exemplary cross section of a semiconductor device 210.

FIG. 3 illustrates an exemplary cross section during a manufacturing process of the semiconductor device 210.

FIG. 4 illustrates an exemplary cross section during the manufacturing process of the semiconductor device 210.

FIG. 5 illustrates an exemplary cross section during the manufacturing process of the semiconductor device 210.

FIG. 6 illustrates an exemplary cross section during the manufacturing process of the semiconductor device 210.

FIG. 7 illustrates an exemplary cross section during the manufacturing process of the semiconductor device 210.

FIG. 8 illustrates an exemplary cross section during the manufacturing process of the semiconductor device 210.

FIG. 9 illustrates an exemplary cross section during the manufacturing process of the semiconductor device 210.

FIG. 10 illustrates an exemplary cross section during the manufacturing process of the semiconductor device 210.

FIG. 11 schematically illustrates an exemplary cross section of a semiconductor device 1100.

FIG. 12 schematically illustrates an exemplary top view of the semiconductor device 1100.

FIG. 13 schematically illustrates a cross section of the semiconductor device 1100 shown in FIG. 12.

FIG. 14 illustrates CV characteristics of an MIS diode described in Exemplary Embodiment 1.

FIG. 15 illustrates CV characteristics of an MIS diode described in Exemplary Embodiment 2.

FIG. 16 illustrates CV characteristics of an MIS diode described in Comparison Example.

FIG. 17(a) is a TEM image observing a boundary between InGaAs of the (111)A plane and Al₂O₃ formed by an ALD method.

FIG. 17(b) is a TEM image observing a boundary between InGaAs of the (100)A plane and Al₂O₃ formed by an ALD method.

FIG. 18 illustrates drain current-drain voltage characteristics of a fabricated field effect transistor.

FIG. 19 is a graphic representation of values of effective mobility versus carrier density.

FIG. 20 is an SEM image of a plurality of pieces of upper-layer compound semiconductor 1200 laterally grown on an inhibition layer.

FIG. 21 is a TEM image of a piece of the upper-layer compound semiconductor 1200 of FIG. 20 showing its cross section.

FIG. 22 is an enlarged TEM image of the cross section of FIG. 21 around the surface of the upper-layer compound semiconductor.

### MODE FOR CARRYING OUT THE INVENTION

Some aspects of the invention will now be described based on embodiments, which do not intend to limit the scope of the present invention, but exemplify the invention. Embodiments are hereunder described with reference to the accompanying drawings. Identical reference numerals will be given to the corresponding or analogous elements in the drawings, and those descriptions can not be repeated. The drawings are schematic and the thicknesses, dimensions and ratios of elements illustrated in the drawings are not necessarily drawn to scale. Moreover, for simplicity and clarity of illustration, the dimensions and scales can be different among the drawings.

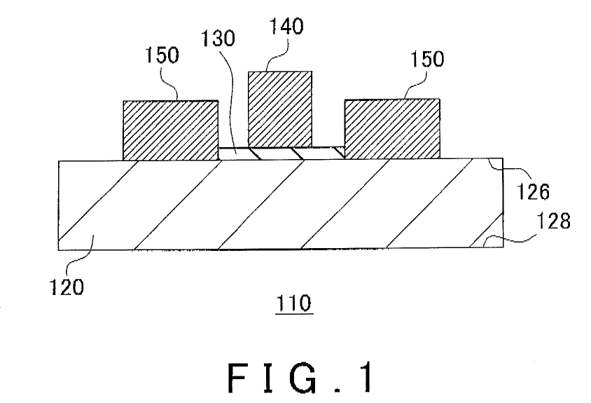

FIG. 1 schematically illustrates an exemplary cross section of a semiconductor device 110. The semiconductor device 110 includes compound semiconductor 120, an insulating material 130, an MIS-type electrode 140 and a pair of input/output electrodes 150. The compound semiconductor 120 has a first main plane 126 and a second main plane 128. The pair of the input/output electrodes 150 is disposed on the first main plane 126. The input/output electrodes 150 are electrically connected to the compound semiconductor 120. The MIS-type electrode 140 and the compound semiconductor 120 are electrically isolated each other by the insulating material 130.

The semiconductor device 110 can be an MIS-type field effect transistor using the compound semiconductor 120 for a channel layer. For example, the semiconductor device 110 is an N-channel MIS-type field effect transistor. The semiconductor device 110 can be an N-channel MIS-type field effect transistor using In_{z}Ga_{1-z}As_{z′}Sb_{1-z′} (where 0≦z≦1, 0≦z′≦1) or InₓGa₁₋ₓAs_{y}P_{1-y} (where 0≦x≦1, 0≦y≦1) for the channel layer.

The compound semiconductor 120 has, for example, a zinc-blende-type crystal structure. As having such crystal structure, constituent elements of the compound semiconductor 120 are arranged in the (111) plane of the compound semiconductor 120 or a plane equivalent to the (111) plane.

The compound semiconductor 120 is preferably a III-V Group compound semiconductor having a zinc-blende-type crystal structure. The compound semiconductor 120 can include more than one III-V Group compound semiconductor. The compound semiconductor 120 can be a III-V Group compound semiconductor that includes, for example, at least one member selected from among Al, Ga and In as the group-III element, and at least one member selected from among N, P, As and Sb as the group-V element. The compound semiconductor 120 can include GaAs, InGaAs, InP, InSb and InAs. The compound semiconductor 120 can include In_{z}Ga_{1-z}As_{z′}Sb_{1-z′} (where 0≦z≦1, 0≦z′≦1) or InₓGa₁₋ₓAs_{y}Sb_{1-y} (where 0≦x≦1, 0≦y≦1).

The compound semiconductor 120 can be an N-type semiconductor in which donor impurities are doped. An example of the donor impurities includes Si, Se, Ge, Sn and Te. The compound semiconductor 120 can be a P-type semiconductor in which acceptor impurities are doped. An example of the acceptor impurities include C, Be, Zn, Mn and Mg.

The compound semiconductor 120 is formed by, for example, an epitaxial growth method such as a metal organic chemical vapor deposition method (hereunder also referred as to a MOCVD method) and a molecular beam epitaxy method (hereunder also referred to as a MBE method). The compound semiconductor 120 can be epitaxially grown on the (111) plane of Si crystal contained in a Si wafer or a silicon-on-insulator (SOI) wafer. The compound semiconductor 120 can be epitaxially grown on the (111) plane of SiₓGe₁₋ₓ crystal (where 0≦x<1) contained in a Ge wafer or a germanium-on-insulator (GOI) wafer. The compound semiconductor 120 can be epitaxially grown on the (111) plane of GaAs crystal contained in a GaAs wafer.

As described above, the compound semiconductor 120 having the (111) plane or the plane equivalent to the (111) plane, for example, in the first main plane 126 can be obtained. In this case, the (111) plane of the compound semiconductor 120 or the plane equivalent to the (111) plane of the compound semiconductor 120 is arranged in parallel to the first main plane 126 of the compound semiconductor 120, and is arranged in substantially parallel to the (111) plane of the Si crystal, SiₓGe₁₋ₓ crystal or GaAs crystal contained in the wafer on which the compound semiconductor 120 is epitaxially grown. Here, “substantially parallel” used in this description encompasses directions that are slightly tilted away from the parallel in consideration of a production error in a wafer or each component.

A plane that has an off angle with respect to the (111) plane of the compound semiconductor 120 or a plane that has an off angle with respect to the plane equivalent to the (111) plane of the compound semiconductor 120 can be substantially parallel to the first main plane 126 or the (111) plane of the Si crystal, SiₓGe₁₋ₓ crystal or GaAs crystal. Here, “the off angle with respect to the (111) plane” means the angle formed between the surface of the compound semiconductor 120 and the crystallographically defined (111) plane. The off angle is, for example, no less than 0.5° nor more than 10°, more preferably, no less than 2° nor more than 6°.

The compound semiconductor 120 forms a part of a semiconductor wafer in which, for example, a III-V Group compound semiconductor having a zinc-blende-type crystal structure is provided. For example, the first main plane 126 of the compound semiconductor 120 serves as the main plane of the above-described semiconductor wafer. The first main plane 126 of the compound semiconductor 120 is a plane on which an electronic element is fabricated. The electronic element can be a schottky-gate type MESFET, a HEMT, a p-HEMT, a HBT or an MISFET using the compound semiconductor for its channel layer.

The semiconductor wafer can include a base wafer such as a Si wafer, an SOI wafer, a Ge wafer, a GOI wafer and a sapphire wafer, and the compound semiconductor 120 that includes the III-V Group compound semiconductor having a zinc-blende-type crystal structure and the like. The compound semiconductor 120 is provided on, for example, the above-mentioned base wafer. The compound semiconductor 120 can be locally formed on the base wafer.

The compound semiconductor 120 and the MIS-type electrode 140 are electrically isolated each other by the insulating material 130. The insulating material 130 is in contact with the (111) plane of the compound semiconductor 120 or the plane equivalent to the (111) plane of the compound semiconductor 120. The insulating material 130 can be in contact with the plane that has an off angle with respect to the (111) plane of the compound semiconductor 120 or the plane that has an off angle with respect to the plane equivalent to the (111) plane.

The insulating material 130 includes, for example, at least one member selected from among Al₂O₃, Ga₂O₃, La₂O₃, AlN, GaN, SiO₂, ZrO₂, HfO₂, HfₓSi₁₋ₓO_{y} (where 0≦x≦1, 1≦y≦2), HfₓAl₂₋ₓO_{y} (where 0≦x≦2, 1≦y≦3), Hf_{x′}Si_{1-x′}O_{y′}N_{2-y′} (where 0≦x′≦1, 1≦y′≦2) and Ga_{2-x″}Gd_{x″}O₃ (where 0≦x″≦2), or a layered structure thereof. The insulating material 130 can include a III-V Group compound semiconductor that contains Al and that has a zinc-blende-type crystal structure, an oxide of the III-V Group compound semiconductor that contains Al and that has a zinc-blende-type crystal structure. Other examples of the insulating material 130 includes tantalum oxide, silicon nitride and silicon oxynitride.

The insulating material 130 is formed by, for example, a vacuum evaporation method, a CVD method, a MBE method or an atomic layer deposition method (hereunder also referred to as an ALD method). In particular, by using the ALD method and the MOCVD method to form the insulating material 130, it is possible to obtain a good-quality insulating material 130. The insulating material 130 is preferably annealed under vacuum or an atmosphere containing hydrogen after it is formed by the ALD method or the MOCVD method. In this way, excessive oxygen contained in the insulating material can be removed. Moreover, by using hydrogen, unnecessary defects can be deactivated.

The insulating material 130 is formed of a forming material that includes a reducing precursor containing one member selected from among Al, Ga, La, Gd, Si, Zr or Hf, and oxygen or an oxidizing precursor containing oxygen (water, ozone or the like) or a precursor containing nitrogen (ammonia, hydrazine series, amine series or the like). The insulating material 130 can be formed by the ALD method or the MOCVD method. With a combination of the reducing precursor and the oxidizing precursor, an oxide insulating material 130 (Al₂O₃, HfO₂, HfSiO₂ or the like) is formed. With a combination of the reducing precursor and the precursor containing nitrogen, a nitride insulating material 130 (GaN, AlN, Si₃N₄ or the like) is formed. With a combination of the reducing precursor, the oxidizing precursor and the precursor containing nitrogen, an oxynitride insulating material 130 (SiON or the like) is formed. In the ALD method, these precursors are alternately provided in a low-temperature adsorption mode, whereas in the MOCVD method, these are simultaneously provided.

When the insulating material 130 is the III-V Group compound semiconductor containing Al and having a zinc-blende-type crystal structure, the insulating material 130 can be formed by, for example, an ALD method or MOCVD method using a reducing precursor that contains a group-III element and a reducing precursor that contains a group-V element as the forming material. When the insulating material 130 is the oxide of the III-V Group compound semiconductor containing Al and having a zinc-blende-type crystal structure, it can be formed, for example, through the following process. By the ALD method or the MOCVD method using the reducing precursor that contains a group-III element and a reducing precursor that contains a group-V element as the forming material, a III-V Group compound semiconductor, which serves as a precursor for the insulating material 130, is firstly formed. The precursor can include a material that reduces resistivity when it is oxidized. The precursor can be a III-V Group compound semiconductor containing Al and having a zinc-blende-type crystal structure. A ratio of Al to Ga in the III-group element contained in the III-V Group compound semiconductor can be 40% or more, preferably, 60% or more. The precursor can be AlGaAs or AlInGaP.

The precursor is then oxidized. The precursor is oxidized, for example, through a heat treatment under an oxygen atmosphere. For instance, a wafer on which the precursor is formed is retained in a reaction chamber, and a temperature and a pressure inside the reaction chamber is set to about 500° C. and 100 kPa respectively. A carrier gas including water is supplied to the reaction chamber, and then the precursor is oxidized. The carrier gas is, for example, an inert gas such as an argon gas, or hydrogen. Where the precursor is AlGaAs, AlInGaP or the like, the resistivity is increased when the precursor is oxidized. Therefore, the insulating material 130 formed by oxidizing the precursor has a greater insulation than that of the precursor.

Voltage is applied to the MIS-type electrode 140. The semiconductor device 110 can control a depletion layer formed in the compound semiconductor 120 with the voltage applied to the MIS-type electrode 140. The MIS-type electrode 140 is, for example, a gate electrode of a transistor. The semiconductor device 110 can control a current running between the pair of the input/output electrodes 150 with the voltage applied to the MIS-type electrode 140.

The MIS-type electrode 140 is in contact with the insulating material 130. The MIS-type electrode 140 can include a metal conductive material. The MIS-type electrode 140 includes, for example, at least one member selected from among TaC, TaN, TiN, Pt, Ti, Au, W and Pd as the metal conductive material. The metal conductive material is semiconductor or silicide (metal-silicon compound), which is a highly-doped and degenerated single-crystal, polycrystal or amorphous semiconductor. Because the semiconductor or the silicide is highly doped, it is degenerated. The metal conductive material can be a composite structure (layered structure) of the semiconductors and the silicides. The MIS-type electrode 140 is formed by, for example, a sputter method, a deposition method or an ALD method.

The input/output electrodes 150 each can be in ohmic-contact with the compound semiconductor 120. The ohmic-contact is a resistive contact in which the resistivity is substantially constant irrespective of a direction of the current and a magnitude of the voltage. The input/output electrodes 150 are formed of, for example, PtTi or AuGeNi. The input/output electrodes 150 are formed by, for example, a vacuum evaporation method.

The input/output electrodes 150 can be metal electrodes. The input/output electrodes 150 can be in schottky-contact with the compound semiconductor 120. When the input/output electrodes 150 are in schottky-contact with the compound semiconductor 120, a rectification property is generated in the semiconductor device 110. The input/output electrodes 150 each are connected to a current source such that the schottky contact is directed forward with respect to a direction in which the current flows, and thereby a contact resistance of the schottky contact can be lowered at prescribed operating conditions. In this case, the input/output electrodes 150 are electrically connected to the compound semiconductor 120 even when the input/output electrodes 150 are in schottky-contact with the compound semiconductor 120.

As described above, the compound semiconductor 120 has a zinc-blende-type crystal structure. The insulating material 130 is in contact with the (111) plane of the compound semiconductor 120 or the plane equivalent to the (111) plane of the compound semiconductor 120. The insulating material 130 can be in contact with the plane having an off angle with respect to the (111) plane of the compound semiconductor 120 or the plane that has an off angle with respect to the plane equivalent to the (111) plane. In this way, interface states generated at the boundary between the compound semiconductor 120 and the insulating material 130 can be reduced. Moreover, it is possible to obtain the insulating material 130 with a low defect density.

The insulating material 130 preferably is in contact with the (111)A plane of the compound semiconductor 120, a plane equivalent to the (111)A plane, a plane having an off angle with respect to the (111)A plane, and a plane having an off angle with respect to the plane equivalent to the (111)A plane. For example, when the compound semiconductor 120 is made of GaAs, Ga elements are arranged in the (111)A plane of the compound semiconductor 120, and As elements are arranged in the (111)B plane of the compound semiconductor 120. Compared to the electron level of oxides of As element, the electron level of oxides of Ga element is less prone to the interface states at the boundary of GaAs. Therefore, when the insulating material 130 is in contact with the (111)A plane of the compound semiconductor 120, the interface states can be further reduced.

Although the above-described semiconductor device 110 has two input/output electrodes 150, the semiconductor device 110 can include a single input/output electrode. For example, when the semiconductor device 110 is a diode, the semiconductor device 110 has a single input/output electrode. In this case, the input/output electrode means an electrode which is used for input or output. When the semiconductor device 110 is a bidirectional thyristor, the semiconductor device 110 has two or more input/output electrodes. When the semiconductor device 110 has a plurality of electronic elements, the semiconductor device 110 can have two or more input/output electrodes.

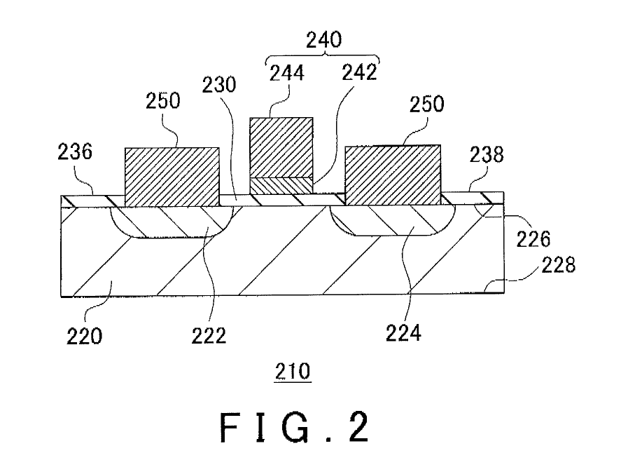

FIG. 2 schematically illustrates an exemplary cross section of a semiconductor device 210. The semiconductor device 210 includes compound semiconductor 220, an insulating material 230, an MIS-type electrode 240 and a pair of input/output electrodes 250. The semiconductor device 210 can include an insulating material 236 and an insulating material 238. The compound semiconductor 220 has a first main plane 226 and a second main plane 228.

The semiconductor device 210 can be a N-channel or P-channel MIS-type field effect transistor (hereunder also referred to as MISFET) using the compound semiconductor 220 for a channel layer. The semiconductor device 210 can be an N-channel MISFET or P-channel MISFET using In_{z}Ga_{1-z}As_{z′}Sb_{1-z′} (where 0≦z≦1, 0≦z′≦1) or InₓGa₁₋ₓAs_{y}P_{1-y} (where 0≦x≦1, 0≦y≦1) for the channel layer.

The compound semiconductor 220 and the compound semiconductor 120 are equivalent. Therefore, only the different features from those of the compound semiconductor 120 will be described and descriptions for the rest of the features will be hereunder omitted. The compound semiconductor 220 has a source region 222 and a drain region 224. The source region 222 and the drain region 224 are formed by, for example, doping impurities in the compound semiconductor 220. The impurities are, for example, donor impurities or acceptor impurities. For example, after impurities are introduced to the compound semiconductor 220 by ion implantation or the like, the compound semiconductor 220 is annealed and the impurities are doped therein.

The insulating material 230 and the insulating material 130 are equivalent. Thus, description of the insulating material 230 will be hereunder omitted. The insulating material 236 and the insulating material 238 protect the first main plane 226 of the compound semiconductor 220. The insulating material 236 and the insulating material 238 are formed, for example, through the same manufacturing process as that of the insulating material 230.

The MIS-type electrode 240 and the MIS-type electrode 140 are equivalent. Therefore, only the different features from those of the MIS-type electrode 140 will be described and descriptions for the rest of the features will be hereunder omitted. The MIS-type electrode 240 includes an intermediate layer 242 and a conductive layer 244. A different feature from the MIS-type electrode 140 is that the MIS-type electrode 240 is in contact with the insulating material 230 and has the intermediate layer 242.

The intermediate layer 242 is in contact with the insulating material 130. The intermediate layer 242 has an influence on a threshold voltage of the MISFET. The intermediate layer 242 is made of, for example, a metal conductive material. The intermediate layer 242 can include for example, at least one member selected from among TaC, TaN, TiN, Pt, Ti, Au, W and Pd as the metal conductive material. The intermediate layer 242 is formed by, for example, a sputter method, a deposition method or an ALD method.

The conductive layer 244 is made of, for example, a material of which resistivity is smaller than that of the intermediate layer 242. The conductive layer 244 can be formed of a metal conductive material. The conductive layer 244 can be formed of the same material as that of the input/output electrodes 250. The conductive layer 244 is formed of, for example, Ti, Au, Al, Cu or W. The conductive layer 244 can be formed through the same manufacturing process as that of the input/output electrodes 250. The conductive layer 244 is formed by, for example, a vacuum evaporation method.

The input/output electrodes 250 and the input/output electrodes 150 are equivalent. Therefore, only the different features from those of the input/output electrodes 150 will be described and descriptions for the rest of the features will be hereunder omitted. One of a pair of the input/output electrodes 250 is in contact with, for example, the source region 222. The other of the input/output electrodes 250 is in contact with the drain region 224.

The compound semiconductor 220 has a zinc-blende-type crystal structure. The insulating material 230 is in contact with the (111) plane of the compound semiconductor 220 or a plane equivalent to the (111) plane. The insulating material 230 can be in contact with the (111) plane of the compound semiconductor 120 or the plane equivalent to the (111) plane. The insulating material 230 can also be in contact with the plane having an off angle with respect to the (111) plane of the compound semiconductor 120 or the plane that has an off angle with respect to the plane equivalent to the (111) plane. In this way, interface states generated at the boundary between the compound semiconductor 220 and the insulating material 230 can be reduced. Moreover, it is possible to obtain the insulating material 230 with a low defect density.

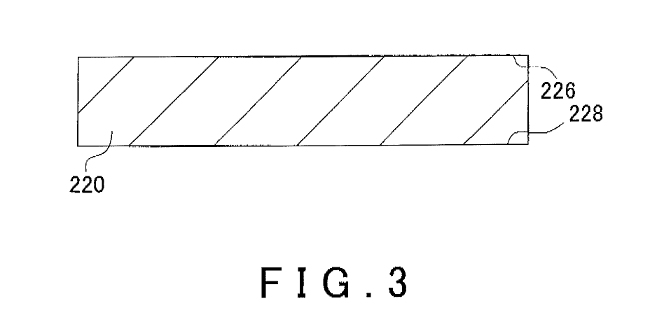

An example of a manufacturing method for the semiconductor device 210 will be now described with reference to FIGS. 3 through 10. FIGS. 3 through 10 illustrate exemplary cross sections during a manufacturing process of the semiconductor device 210.

FIG. 3 shows a step of preparing the compound semiconductor 220. Referring to FIG. 3, the compound semiconductor 220 is firstly prepared. The compound semiconductor 220 is formed, for example, through the following process. At the beginning of the process, a base wafer on which the compound semiconductor 220 is formed is prepared. The base wafer is, for example, selected from a Si wafer, an SOI wafer and a GOI wafer. The Si wafer and the SOI wafer contain Si crystals. The base wafer can be a Ge wafer, a sapphire wafer, a GaAs wafer or an InP wafer.

The compound semiconductor 220 is formed on at least a part of the base wafer by an epitaxial growth method such as a MOCVD method and a MBE method. The compound semiconductor 220 can be locally formed on a main plane of the base wafer. The compound semiconductor 220 is formed such that the (111) plane of the compound semiconductor 220 or a plane equivalent to the (111) plane is arranged in parallel to the main plane of the base wafer. The compound semiconductor 220 can be formed such that a plane having an off angle with respect to the (111) plane of the compound semiconductor 220 or a plane having an off angle with respect to the plane equivalent to the (111) plane is arranged in parallel to the main plane of the base wafer. The compound semiconductor 220 can be formed on the (111) plane of Si crystal of a Si wafer or SOI wafer.

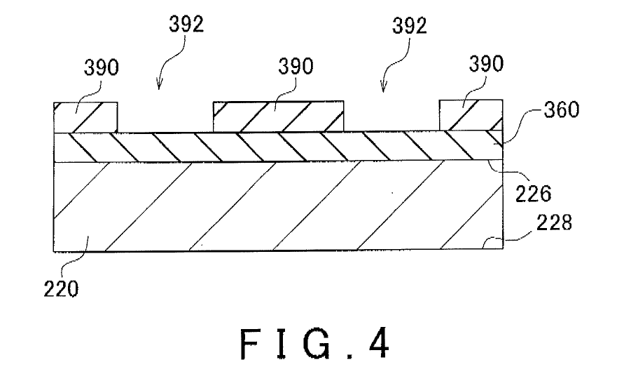

FIG. 4 schematically illustrates an example of a step of forming a photomask 390 which is patterned in a prescribed shape on the compound semiconductor 220, in preparation for an impurity introducing step. Referring to FIG. 4, a sacrificial film 360 is formed on the first main plane 226 of the compound semiconductor 220. The sacrificial film 360 protects the compound semiconductor 220 during the impurity introducing step. The sacrificial film 360 is, for example, a SiO₂ thin film.

The sacrificial film 360 can be formed by, for example, a sputter method, a deposition method or an ALD method. The sputter method can be an ion-beam sputtering method (hereunder also referred to as an IBS method). After resist is applied on the sacrificial film 360, the resist is patterned by a photolithography method so as to obtain the photomask 390. An opening 392 is formed in the photomask 390. The opening 392 exposes at least a part of the sacrificial film 360.

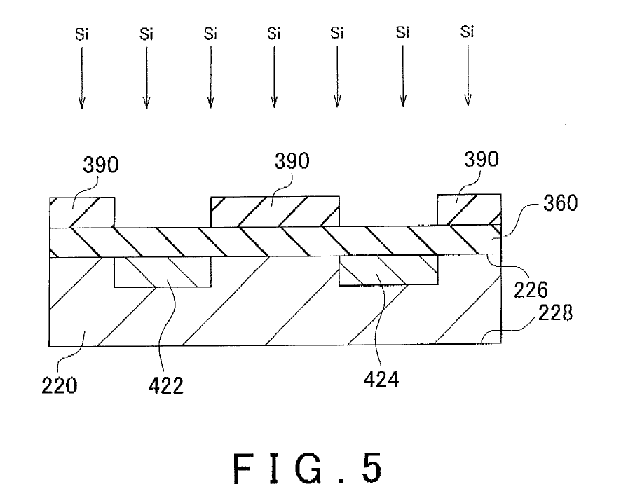

FIG. 5 schematically illustrates an example of a step in which impurities are introduced in the compound semiconductor 220. Referring to FIG. 5, impurities are introduced through the opening 392 in the compound semiconductor 220. In this way a region 422 that serves as a source region and a region 424 that serves as a drain region are formed in the compound semiconductor 220. For example, Si is introduced as the impurities in the compound semiconductor 220 by an ion-implantation method. When an N-type MIS diode or an N-channel MISFET is formed, the impurities can be donor impurities such as Si, Se, Ge, Sn and Te. When a P-type MIS diode or a P-channel MISFET is formed, the impurities can be acceptor impurities such as Be, Zn, Mn and Mg. A method of introducing the impurities is not limited to the ion-implantation method.

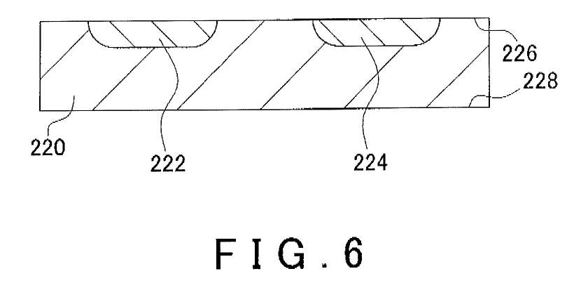

FIG. 6 schematically illustrates an example of a step of activating the impurities introduced in the compound semiconductor 220. Referring to FIG. 6, the compound semiconductor 220 in which the impurities are introduced is annealed so as to form the source region 222 and the drain region 224 in the compound semiconductor 220. The source region 222 and the drain region 224 are formed, for example, through the following process.

The photomask 390 is removed using a resist remover solution. Annealing is the performed as the sacrificial film 360 is disposed on the compound semiconductor 220. Through the above-described process, the source region 222 and the drain region 224 are formed. The annealing is, for example, rapid thermal annealing (hereunder also referred to as RTA). The annealing is performed, for example, at a temperature of 800° C. for 5 minutes. After that, the sacrificial film 360 is removed by etching or the like. As a result, the compound semiconductor 220 having the source region 222 and the drain region 224 is obtained.

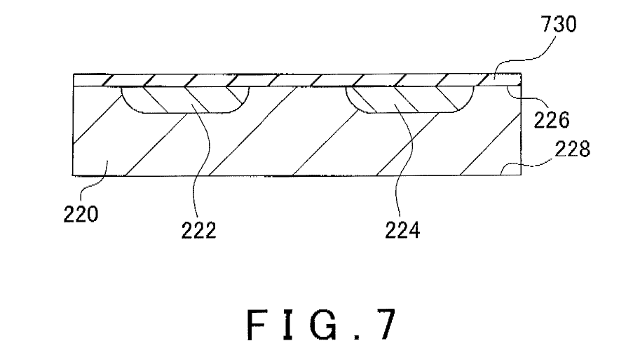

FIG. 7 schematically illustrates an example of a step of forming an insulating material 730. Referring to FIG. 7, the insulating material 730 is formed on the first main plane 226 of the compound semiconductor 220. The insulating material 730 is formed by, for example, an ALD method. In this way, formed is the insulating material 730 which is in contact with the (111) plane of the compound semiconductor 220, a plane equivalent to the (111) plane, a plane that has an off angle with respect to the (111) plane of the compound semiconductor 220, or a plane that has an off angle with respect to the plane equivalent to the plane (111) of the compound semiconductor 220. After the insulating material 730 is formed by an ALD method, it can be annealed under vacuum or under the atmosphere containing hydrogen. The annealing is performed, for example, at a temperature of 450° C. for 2 minutes.

The insulating material 730 is formed by, for example, an ALD method or a MOCVD method. The insulating material 730 can be formed by an ALD method or a MOCVD method under an atmosphere containing a reducing material. For example, a source gas used for the formation of the insulating material 730 includes a reducing material that exerts a reduction action to oxygen or oxides when it is in a ground state, an excited state, an ionized state or a radical state. In this way, the insulating material 730 can be formed under the atmosphere containing the reducing material.

Consequently, even when the surface of the compound semiconductor 220 is covered with an oxide film, the oxide film can be efficiently removed so that the MIS characteristics of the semiconductor device 210 can be improved. The source gas can be an organic metal compound or hydride that contains constituent elements of the insulating material 730. For example, when the insulating material 730 is made of Al₂O₃, trimethyl-aluminum can be used as the reducing material.

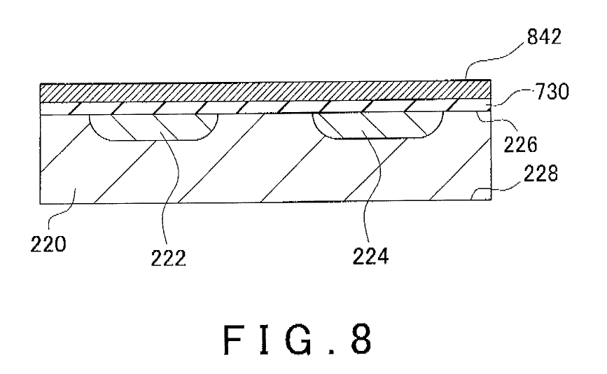

FIG. 8 schematically illustrates an exemplary forming process of the MIS-type electrode 240. Referring to FIG. 8, an intermediate layer 842 that is in contact with the insulating material 730 is formed. The intermediate layer 842 is a thin film of a metal conductive material such as TaC, TaN, TiN, Ti, Au, W, Pt and Pd. The intermediate layer 842 is formed by, for example, a sputter method, a deposition method or an ALD method. The sputter method is, for example, an IBS method.

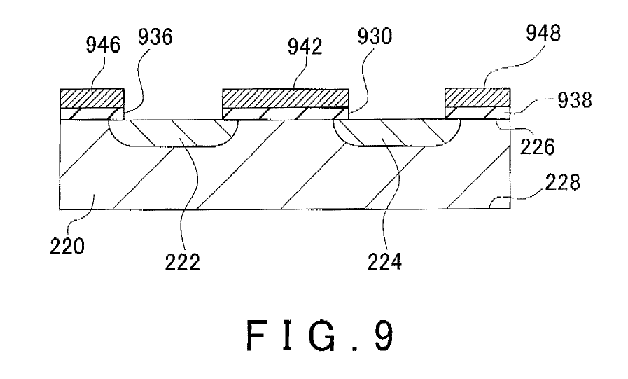

FIG. 9 schematically illustrates the exemplary forming process of the MIS-type electrode 240. Referring to FIG. 9, the insulating material 730 is patterned by a photolithography method or the like, and an insulating material 930, an insulating material 936 and an insulating material 938 are formed. Furthermore, the intermediate layer 842 is patterned by a photolithography method or the like, and an intermediate layer 942, an intermediate layer 946 and an intermediate layer 948 are formed. In this way, at least a part of the source region 222 and the drain region 224 of the compound semiconductor 220 are exposed. The insulating material 730 and the intermediate layer 842 are patterned, for example, through the following process.

First, resist is applied on the intermediate layer 842 shown in FIG. 8, and the resist is then patterned by a photolithography method such as etching. Next, the insulating material 730 and the intermediate layer 842 are patterned using the resist as a mask. In this way, the insulating material 930 and the intermediate layer 942 can be formed in substantially the same shape. In the same manner, the insulating material 936 and the intermediate layer 946 can be formed in substantially the same shape. In the same manner, the insulating material 938 and the intermediate layer 948 can be formed in substantially the same shape. After that, the resist is removed using a resist remover solution.

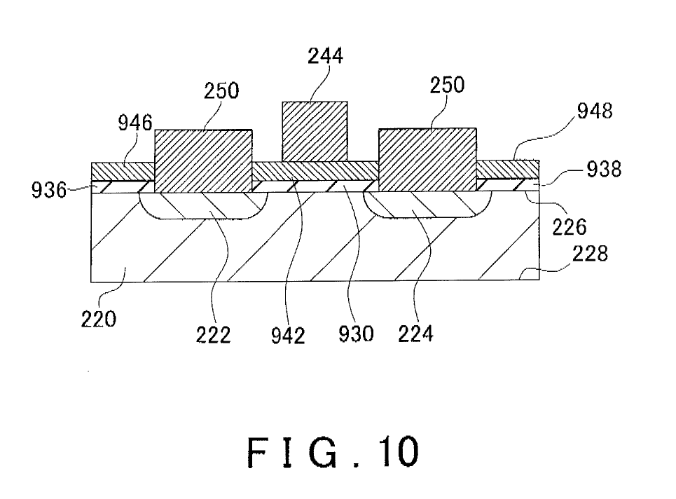

FIG. 10 schematically illustrates the exemplary forming process of the MIS-type electrode 240. Referring to FIG. 10, the conductive layer 244 is formed on the intermediate layer 942. Moreover, the pair of the input/output electrodes 250 is formed on the source region 222 and the drain region 224. In this way, the pair of the input/output electrodes 250 is electrically connected to the compound semiconductor 220. The conductive layer 244 and the input/output electrodes 250 can be formed in the same manufacturing step. The conductive layer 244 and the input/output electrodes 250 can be formed, for example, through the following process.

After resist is applied, the resist is patterned by a photolithography method such as etching, and then a mask is formed. The above-mentioned step is, for example, a multi-layer photoresist process. In other words, multiple photoresist layers with various resist types and different baking temperatures are deposited so as to form the mask. In this way, it is possible to form a mask which can be easily lifted off.

Subsequently, a conductive thin film is formed by, for example, a vacuum evaporation method. The conductive thin film can include multiple thin films. For example, after a Ti thin film is formed by a vacuum evaporation method, an Au thin film is formed by a vacuum evaporation method. In this way, the layered film including the Ti thin film and the Au thin film is formed. After that, a part of the layered film, which is deposited on the mask, is removed by a lift-off method so as to obtain the conductive layer 244 and the pair of the input/output electrodes 250. In this way, the pair of the input/output electrode 250 is electrically connected to the compound semiconductor 220.

After that, the insulating material 930 and the intermediate layer 942 are patterned by a photolithography method or the like so as to separate the conductive layer 244 from the pair of the input/output electrodes 250. The insulating material 930 and the intermediate layer 942 can be patterned using the conductive layer 244 as a mask. Through the above-described processes, the semiconductor device 210 is fabricated.

Although the MIS-type electrode 240 is formed before the pair of the input/output electrodes 250 is formed in this embodiment, the manufacturing method for the semiconductor device 210 is not limited to this. For example, the semiconductor device 210 can be fabricated even when an order of forming the insulating material 230, the MIS-type electrode 240 and the input/output electrode 250 is different from the above-described order.

As another example of the manufacturing method for the semiconductor device 210, the pair of the input/output electrodes 250 can be formed before the MIS-type electrode 240 or the insulating material 230 is formed. For example, the compound semiconductor 220 is prepared. The input/output electrodes 250 which are electrically connected to the compound semiconductor 220 is then formed. Subsequently, the MIS-type electrode 240 is formed after the insulating material 230 is formed. In this way, the semiconductor device 210 is manufactured.

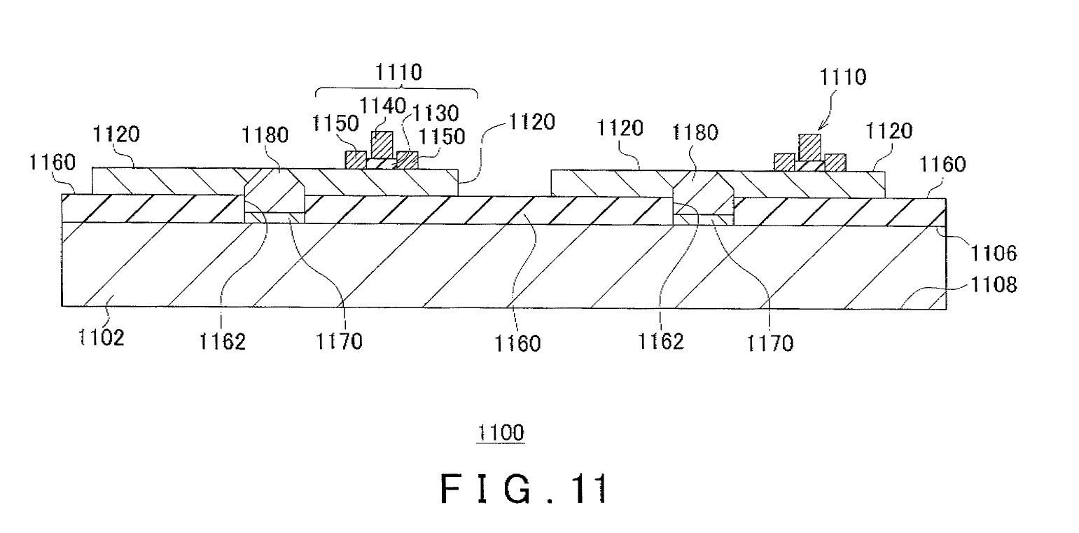

FIG. 11 schematically illustrates an exemplary cross section of a semiconductor device 1100. The semiconductor device 1100 includes a base wafer 1102, an inhibition layer 1160, a seed crystal 1170, a seed compound semiconductor 1180 and a lateral compound semiconductor 1120. The base wafer 1102 has a first main plane 1106 and a second main plane 1108. An opening 1162 is formed in the inhibition layer 1160. In the lateral compound semiconductor 1120, an MISFET 1110 that uses the lateral compound semiconductor 1120 for its channel layer is formed.

In at least a part of the semiconductor device 1100, the base wafer 1102, the inhibition layer 1160 and the lateral compound semiconductor 1120 are disposed in this order in a direction substantially perpendicular to the first main plane 1106. For example, the inhibition layer 1160 is formed so as to be in contact with the first main plane 1106. At least a part of the seed crystal 1170 and the seed compound semiconductor 1180 can be disposed inside the opening 1162. Inside the opening 1162, the base wafer 1102, the seed crystal 1170 and the seed compound semiconductor 1180 are disposed in this order in the direction substantially perpendicular to the first main plane 1106. The expression “a direction substantially perpendicular to” used here encompasses not only the definite perpendicular direction but also directions that are slightly tilted away from the perpendicular direction in consideration of a production error in a wafer or each component.

The base wafer 1102 is, for example, one member selected from among a Si wafer, an SOI wafer and a GOI wafer. The Si wafer or the SOI wafer contains Si crystals. The base wafer 1102 can be a Ge wafer, a sapphire wafer, a GaAs wafer or an InP wafer.

The inhibition layer 1160 inhibits crystal growth of the compound semiconductor. When crystal of the compound semiconductor is epitaxially grown by a MOCVD method, the inhibition layer 1160 inhibits the compound semiconductor from growing epitaxially on the surface of the inhibition layer 1160. The inhibition layer 1160 is, for example, a silicon oxide layer, an aluminum oxide layer, a silicon nitride layer, a silicon oxynitride layer, a tantalum nitride layer or a titanium nitride layer, or a multilayer formed by stacking these layers. The thickness of the inhibition layer 1160 is, for example, from 0.05 to 5 μm. The inhibition layer 1160 is formed by, for example, a CVD method.

The opening 1162 penetrates the inhibition layer 1160 to the first main plane 1106 in a direction substantially perpendicular to the first main plane 1106. The opening 1162 exposes the first main plane 1106. In this way, crystal can be selectively grown inside the opening 1162. The opening 1162 is formed by, for example, a photolithography method such as etching.

The opening 1162 has, for example, an aspect ratio of (√3)/3 or higher. When crystal is formed within the opening 1162 having the aspect ratio of (√3)/3 or higher, the defects such as lattice defects in the crystal are terminated by walls of the opening 1162. Consequently, the surface of the crystal exposed in the opening 1162 has a fine crystallinity at the time when the crystal is formed.

“An aspect ratio of an opening” used here is defined as the result of dividing “the depth of the opening” by “the width of the opening.” For example, an aspect ratio is defined as the result of dividing the etching depth by the pattern width in “Handbook for Electronics, Information and Communication Engineers, Volume 1,” edited by the Institute of Electronics, Information and Communication Engineers, Page 751, 1988, published by Ohmsha. The term “aspect ratio” is used herein to mean a similar meaning to the above.

“The depth of the opening” is defined as the depth of the opening in the direction in which the thin films are stacked on the wafer, and “the width of the opening” is defined as the width of the opening in the perpendicular direction to the stacking direction. When there are more than one opening width exits, the minimum width is used for the calculation of the aspect ratio of the opening. For example, when the opening is shaped as a rectangle when seen in the stacking direction, the width of the opening is defined as the length of the shorter side of the rectangle.

The seed crystal 1170 provides a fine seed plane to the seed compound semiconductor 1180. The seed crystal 1170 prevents impurities existing in the base wafer 1102 or the first main plane 1106 from adversely affecting the crystallinity of the seed compound semiconductor 1180. The seed crystal 1170 is formed inside the opening 1162. The seed crystal 1170 is formed, for example, such that it is in contact with the first main plane 1106. The seed crystal 1170 can include crystal of semiconductor. The seed crystal 1170 can include SiₓGe₁₋ₓ crystal (0≦x<1) or InₓGa₁₋ₓAs_{y}P_{1-y} (0≦x≦1, 0≦y≦1).

The seed crystal 1170 is formed by, for example, a CVD method such as an epitaxial growth method. When it is formed, the inhibition layer 1160 inhibits precursors of the seed crystal from growing to crystal on the surface, and therefore the seed crystal 1170 is selectively grown inside the opening 1162.

It is preferable that the seed crystal 1170 be annealed. In this way, the defect density in the seed crystal 1170 can be reduced, and consequently it is possible to provide a fine seed plane for the seed compound semiconductor 1180. When the opening 1162 has the aspect ratio of (√3)/3 or higher, annealing is not necessarily performed.

Multiple steps of annealing can be performed. For example, after a high-temperature annealing is performed at a temperature below the melting point of the seed crystal 1170, a low-temperature annealing is performed at a temperature lower than that of the high-temperature annealing. The above-mentioned two-phase annealing is repeated for a number of times. When the seed crystal 1170 includes SiₓGe₁₋ₓ crystal (0≦x<1), the temperature and a treating time of the high-temperature annealing are set to, for example, 850 to 900° C. and 2 to 10 minutes. The temperature and a treating time of the low-temperature annealing are set to, for example, 680 to 780° C. and 2 to 10 minutes. Such two-phase annealing is performed, for example, ten times.

The seed compound semiconductor 1180 is formed so as to be in contact with the seed crystal 1170. Specifically, the seed compound semiconductor 1180 has a lattice match or a pseudo lattice match with the seed crystal 1170. The seed compound semiconductor 1180 is, for example, a III-V Group compound semiconductor such as GaAs. The boundary between the seed crystal 1170 and the seed compound semiconductor 1180 can be situated inside the opening 1162. The seed compound semiconductor 1180 is formed by, for example, an epitaxial method such as a MOCVD method.

The base wafer 1102 can be a wafer that has Ge crystal in the first main plane 1106 as a Ge wafer and a GOI wafer does. The seed compound semiconductor 1180 can be InₓGa₁₋ₓAs_{y}P_{1-y} (0≦x≦1, 0≦y≦1) that has a lattice match or a pseudo lattice match with GaAs or Ge. In this case, the seed compound semiconductor 1180 can be formed so as to be in contact with the Ge crystal that faces the first main plane 1106.

“Pseudo lattice match” here means a state it is not a complete lattice match but in which a difference in the lattice constant between two adjacent semiconductors is small and the two semiconductors can be layered each other to an extent where defects due to lattice mismatch do not become prominent. At this point, crystal lattice of each semiconductor is distorted within a range of elastic deformation and the difference in the lattice constant is absorbed. For example, a state in which Ge and GaAs are layered together is referred to as the pseudo lattice match.

The lateral compound semiconductor 1120 is laterally grown along the inhibition layer 1160 with the seed compound semiconductor 1180 serving as a nucleus. The lateral compound semiconductor 1120 is formed by, for example, an epitaxial method such as a MOCVD method. The seed compound semiconductor 1180 and the lateral compound semiconductor 1120 can be integrally formed of the same material.

The lateral compound semiconductor 1120 can be electrically isolated from the base wafer 1102. For example, the seed compound semiconductor 1180 includes a material of which resistivity is higher than that of the seed crystal 1170, and thereby the lateral compound semiconductor 1120 and the seed crystal 1170 are electrically isolated each other. As a result, the lateral compound semiconductor 1120 and the base wafer 1102 are electrically isolated each other.

The expression “electrically isolated” used herein is not limited to a complete isolation between the base wafer 1102 and the lateral compound semiconductor 1120. But it also encompasses a state in which a resistance value between the base wafer 1102 and the lateral compound semiconductor 1120 is sufficiently large so that an electronic element fabricated in the lateral compound semiconductor 1120 operates stably. Moreover, the lateral compound semiconductor 1120 and the base wafer 1102 can be electrically isolated by a PN junction barrier formed anywhere between the lateral compound semiconductor 1120 and the base wafer 1102.

One example of the material of which resistivity is higher than that of the seed crystal 1170 is oxide dielectrics. One example of the oxide dielectrics is an oxide of a III-V Group compound semiconductor including Al and having a zinc-blende-type crystal structure. The III-V Group compound semiconductor including Al and having a zinc-blende-type crystal structure can be AlGaAs or AlInGaP. The oxide can be formed by oxidizing the III-V Group compound semiconductor including Al and having a zinc-blende-type crystal structure after the lateral compound semiconductor 1120 is formed. Another example of the material of which resistivity is higher than that of the seed crystal 1170 includes a III-V Group compound semiconductor including Al and in which oxygen is doped, and a III-V Group compound semiconductor including B.

The MISFET 1110 is an example of the semiconductor device. The MISFET 1110 has the similar structure as that of the semiconductor device 110 or the semiconductor device 210. More specifically, the MISFET 1110 includes an insulating material 1130, an MIS-type electrode 1140 and a pair of input/output electrodes 1150. The insulating material 1130 is equivalent to the insulating material 130 and the insulating material 230. The MIS-type electrode 1140 is equivalent to the MIS-type electrode 140 and the MIS-type electrode 240. The input/output electrodes 1150 are equivalent to the input/output electrodes 150 and the input/output electrodes 250. The input/output electrodes 1150 can be ohmic input/output electrodes or schottky input/output electrodes of which resistivity is low in the current direction.

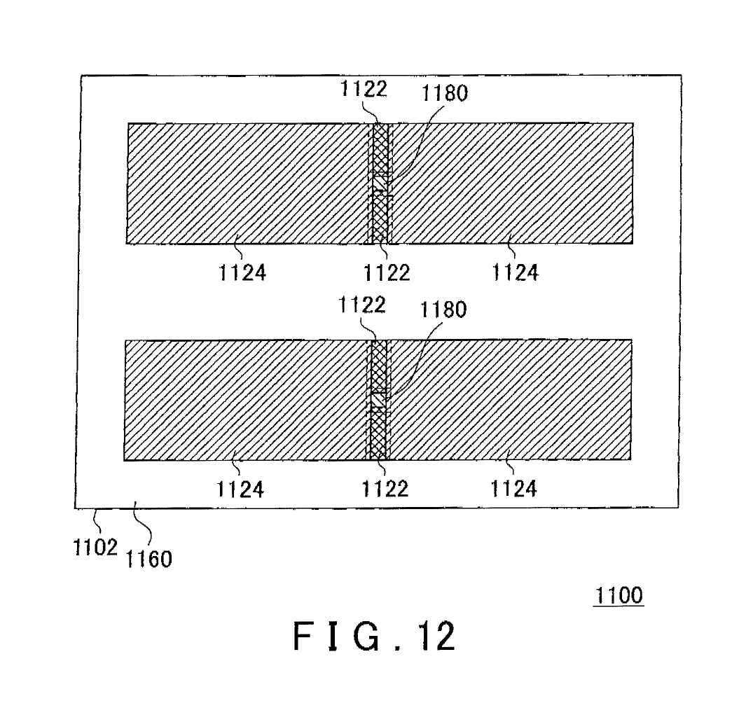

FIG. 12 schematically illustrates an exemplary top view of the semiconductor device 1100. The lateral compound semiconductor 1120 illustrated in FIG. 11 can include a first lateral compound semiconductor 1122 and a second lateral compound semiconductor 1124. The first lateral compound semiconductor 1122 is laterally grown along the inhibition layer 1160 with the seed compound semiconductor 1180 serving as a nucleus. The second lateral compound semiconductor 1124 is laterally grown in a direction different from the direction in which the first lateral compound semiconductor 1122 is grown along the inhibition layer 1160 using the first lateral compound semiconductor 1122 as a nucleus.

For example, the first lateral compound semiconductor 1122 is laterally grown at a width of which length is same as the length of the seed plane of the seed compound semiconductor 1180. The second lateral compound semiconductor 1124 is grown with a plane of the first lateral compound semiconductor 1122 that is not in contact with the seed compound semiconductor 1180 and with a plane of the seed compound semiconductor 1180 that is not in contact with the first lateral compound semiconductor 1122 serving as the seed plane. The first lateral compound semiconductor 1122 and the second lateral compound semiconductor 1124 are, for example, a III-V Group compound semiconductor.

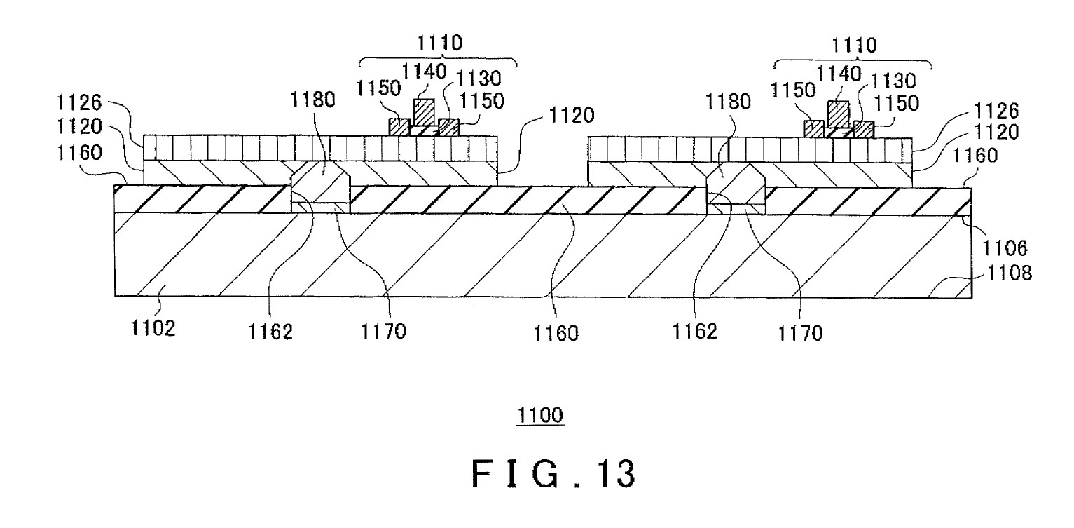

FIG. 13 schematically illustrates a cross section of the semiconductor device 1100 shown in FIG. 12. Referring to FIG. 13, the semiconductor device 1100 further includes an upper-layer compound semiconductor 1126 whose crystal has grown on the lateral compound semiconductor 1120 that includes the first lateral compound semiconductor 1122 and the second lateral compound semiconductor 1124. The upper-layer compound semiconductor 1126 is in contact with upper faces of the seed compound semiconductor 1180, the first lateral compound semiconductor 1122 and the second lateral compound semiconductor 1124, which are shown in FIG. 11 and FIG. 12, and crystal of the upper-layer compound semiconductor 1126 has been grown in a direction perpendicular to the first main plane 1106 of the base wafer 1102. The upper-layer compound semiconductor 1126 has a fine crystallinity compared to those of the first lateral compound semiconductor 1122 and the second lateral compound semiconductor 1124. The MISFET 1110 can be formed on the upper-layer compound semiconductor 1126.

When a III-V Group compound semiconductor is formed by a MOCVD method, a direction in which the III-V Group compound semiconductor is grown can be controlled by adjusting a flow ratio and a partial pressure ratio of a source gas containing a group-III element and a source gas containing a group-V element. More specifically, whether the III-V Group compound semiconductor is laterally grown along the surface of the inhibition layer 1160 or it is further grown in the direction perpendicular to the first main plane 1106 of the base wafer 1102 can be controlled. For example, when InGaAs is formed as the III-V Group compound semiconductor, the larger the partial pressure rate of the source gas containing a group-III element to the source gas containing a group-V element becomes, the more likely the InGaAs is laterally grown.

Although the semiconductor device 1100 includes the seed crystal 1170 that is provided between the base wafer 1102 and the seed compound semiconductor 1180 in the above-described embodiment, the semiconductor device 1100 can not necessarily include the seed crystal 1170. For example, when the seed compound semiconductor 1180 is formed inside the opening that has the aspect ratio of (√3)/3 or higher, the seed compound semiconductor 1180 with a fine crystallinity can be formed even when the semiconductor wafer or the semiconductor device does not have the seed crystal 1170.

### EXEMPLARY EMBODIMENTS

### <Exemplary Embodiment 1>

In order to study the interface states generated at the boundary between the compound semiconductor and the insulating material formed on the surface of the compound semiconductor, an MIS diode was fabricated as an example of the above-described semiconductor device. As an example of the III-V Group compound semiconductor having a zinc-blende-type crystal structure, Si-doped N-type GaAs was used. The MIS diode was fabricated through the following process.

First, Si-doped N-type GaAs was formed as an example of the III-V Group compound semiconductor having a zinc-blende-type crystal. The Si-doped N-type GaAs was formed on a surface of a Si-doped N-type single-crystal GaAs wafer. The Si-doped N-type GaAs was obtained by performing an epitaxial growth on the (111)A plane of the Si-doped N-type single-crystal GaAs wafer. Through the above-mentioned step, the III-V Group compound semiconductor having the (111)A plane in a plane parallel to the main plain of the wafer was formed. The electron concentration of the Si-doped N-type GaAs was 2×10¹⁶/cm³. The thickness was 1 μm.

Next, Cr/Au ohmic electrodes were formed as an example of the input/output electrodes. The Cr/Au ohmic electrodes were formed on a back side of the Si-doped N-type single-crystal GaAs wafer. The Cr/Au ohmic electrodes were formed by a vacuum evaporation method.

Next, an Al₂O₃ thin film was formed as an example of the insulating material. The Al₂O₃ thin film was formed through the following steps. After the Si-doped N-type GaAs formed on the surface of the Si-doped N-type single-crystal GaAs wafer was washed with an ammonia solution, the Si-doped N-type single-crystal GaAs wafer was introduced into a reaction chamber of an ALD film fabrication equipment. After the reaction chamber is sufficiently evacuated, the Si-doped N-type single-crystal GaAs wafer was heated to 250° C. Subsequently, an Al₂O₃ thin film having a thickness of 6 nm was formed on the surface of the Si-doped N-type GaAs by an ALD method in which a trimethyl-aluminum gas and water vapor are alternately supplied into the reaction chamber. After the Al₂O₃ thin film was formed, annealing under vacuum atmosphere was performed. The annealing was performed at 450° C. and for two minutes. After cooling was conducted, the Si-doped N-type single-crystal GaAs wafer was removed from the ALD film fabrication equipment.

Next, as an example of the MIS electrode, an Au thin film was formed. The Au thin film was formed through the following steps. First, a mask that was made of a resist layer was formed on the surface of the Al₂O₃ thin film on the Si-doped N-type single-crystal GaAs wafer, and the resist layer was then patterned so as to form an opening in the resist layer. Subsequently, an Au thin film having a thickness of 250 nm is formed on a surface of the Al₂O₃ thin film exposed in the opening and a surface of the resist layer, by a vacuum evaporation method. The above-mentioned Au layered film deposited on the surface of the resist layer was then removed by a lift-off method.

Through the above described process, obtained is the MIS diode including the Si-doped N-type single-crystal GaAs wafer, the Si-doped N-type GaAs formed on the surface of the GaAs wafer, the Al₂O₃ thin film that is in contact with the (111)A plane of the Si-doped N-type GaAs, the Au thin film that is in contact with the Al₂O₃ thin film, and the Cr/Au ohmic electrode formed on the back side of the GaAs wafer. The interface states of the obtained MIS diode were measured. The measurements of the interface states were conducted by measuring capacitance-voltage characteristics of the MIS diode.

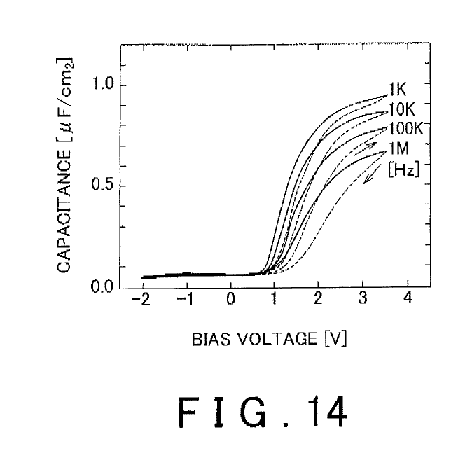

FIG. 14 illustrates the capacitance-voltage characteristics (hereunder also referred to as the CV characteristics) of the MIS diode fabricated in Exemplary Embodiment 1. Referring to FIG. 14, the vertical axis represents a capacitance [μF/cm²] and the horizontal axis represents a bias voltage [V]. CV characteristics at frequencies of 1 k [Hz], 10 k [Hz], 100 k [Hz] and 1 M [Hz] are shown in FIG. 14. In the figure, the solid line represents a CV characteristic when the bias voltage is increased. The dashed line in the figure represents a CV characteristic when the bias voltage is decreased. As shown in FIG. 14, according to the MIS diode fabricated in Exemplary Embodiment 1, fine characteristics having a small frequency dispersion property can be obtained.

### <Exemplary Embodiment 2>

An MIS diode including a Si-doped N-type single-crystal GaAs wafer, a Si-doped N-type GaAs formed on the surface of the GaAs wafer, an Al₂O₃ thin film that is in contact with the (111)B plane of the Si-doped N-type GaAs, an Au thin film that is in contact with the Al₂O₃ thin film, and a Cr/Au ohmic electrode formed on the back side of the GaAs wafer was fabricated. The MIS diode of Exemplary Embodiment 2 was fabricated in the same manner as Exemplary Embodiment 1 except that the Si-doped N-type GaAs was epitaxially grown on the (111)B plane of the Si-doped N-type single-crystal GaAs wafer.

The electron concentration of the Si-doped N-type GaAs was 2×10¹⁶/cm³. The thickness was 1 μm. The interface states of the obtained MIS diode were measured in the same manner as Exemplary Embodiment 1. The measurements of the interface states were conducted by measuring capacitance-voltage characteristics of the MIS diode.

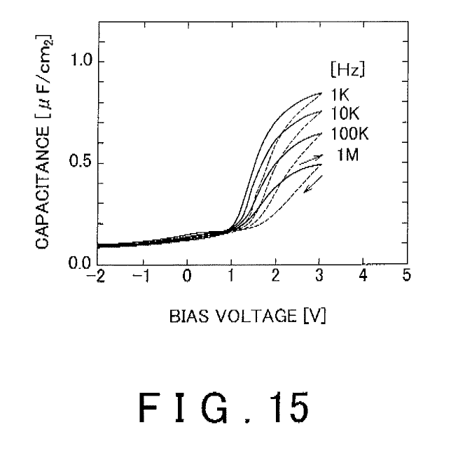

FIG. 15 illustrates the CV characteristics of the MIS diode fabricated in Exemplary Embodiment 2. Referring to FIG. 15, the vertical axis represents a capacitance [μF/cm²] and the horizontal axis represents a bias voltage [V]. CV characteristics at frequencies of 1 k [Hz], 10 k [Hz], 100 k [Hz] and 1 M [Hz] are shown in FIG. 15. In the figure, the solid line represents a CV characteristic when the bias voltage is increased. The dashed line in the figure represents a CV characteristic when the bias voltage is decreased. As shown in FIG. 15, according to the MIS diode fabricated in Exemplary Embodiment 2, fine characteristics having a small frequency dispersion property can be obtained.

<Comparison Example>An MIS diode including a Si-doped N-type single-crystal GaAs wafer, a Si-doped N-type GaAs formed on the surface of the GaAs substrate, an Al₂O₃ thin film that is in contact with the (001) plane of the Si-doped N-type GaAs, an Au thin film that is in contact with the Al₂O₃ thin film, and a Cr/Au ohmic electrode formed on the back side of the GaAs wafer was fabricated as a comparison example. The MIS diode of Comparison Example was fabricated in the same manner as Exemplary Embodiment 1 except that the Si-doped N-type GaAs was epitaxially grown on the (001) plane of the Si-doped N-type single-crystal GaAs wafer.

The electron concentration of the Si-doped N-type GaAs in the MIS diode of Comparison Example was 2×10¹⁶/cm³. The thickness was 1 μm. The interface states of the obtained MIS diode were measured in the same manner as Exemplary Embodiment 1. The measurements of the interface states were conducted by measuring capacitance-voltage characteristics of the MIS diode.

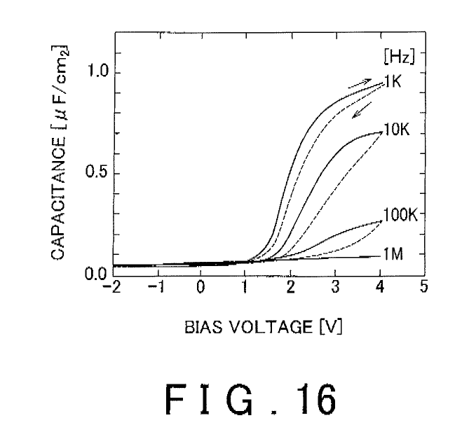

FIG. 16 illustrates the CV characteristics of the MIS diode described in Comparison Example. Referring to FIG. 16, the vertical axis represents a capacitance [μF/cm²] and the horizontal axis represents a bias voltage [V]. CV characteristics at frequencies of 1 k [Hz], 10 k [Hz], 100 k [Hz] and 1 M [Hz] are shown in FIG. 16. In the figure, the solid line represents a CV characteristic when the bias voltage is increased. The dashed line in the figure represents a CV characteristic when the bias voltage is decreased. As shown in FIG. 16, according to the MIS diode fabricated in Comparison Example, the frequency dispersion is very large compared to those of Exemplary Embodiment 1 and Exemplary Embodiment 2.

From the above result, it can be said that since the MIS diodes of Exemplary Embodiment 1 and Exemplary Embodiment 2 have the Al₂O₃ thin film being in contact with the (111)A plane or the (111)B plane of the Si-doped N-type GaAs, they have the interface states that are reduced compared to those of the MIS diode having the Al₂O₃ thin film being in contact with the (001) plane of the Si-doped N-type GaAs. Moreover, from the above result, it is apparent that switching devices and analog devices appropriate for high-frequency operations and high-power operations can be fabricated by adopting such MIS-type electrodes as gate electrodes of transistors.

In other words, an MIS-type field effect transistor that includes: a III-V Group compound semiconductor having a zinc-blende-type crystal structure; an insulating material being in contact with the (111)A plane or the (111)B plane of the III-V Group compound semiconductor, or a plane of the III-V Group compound semiconductor equivalent to the (111)A plane or the (111)B plane; an MIS-type electrode including metal conductive material and being in contact with the insulating material; and a pair of input/output electrodes electrically connected to the III-V Group compound semiconductor, can be used as a switching device or an analog device, which is appropriate for high-frequency operations and high-power operations.

### <Exemplary Embodiment 3>

A field effect transistor was fabricated by using the method described above with reference to FIG. 3 through FIG. 10. The compound semiconductor 120, which is p-type InGaAs, was epitaxially grown on a p-type InP wafer. The p-type InGaAs was formed such that a ratio of In and Ga became 0.53:0.47, the p-type carrier density became 3×10¹⁶ cm⁻³, and the p-type InGaAs was epitaxially grown such that it's surface became the (111)A plane. After Al₂O₃ was formed 6 nm thick as the sacrificial film 360 by the ALD method, the photomask 390 was formed and Si was ion-implanted. Conditions used for the ion implantation were an injection dose of 2×10¹⁴ cm ⁻², and an accelerating voltage of 30 keV.

After the photomask 390 was removed, the source region 222 and the drain region 224 were formed by conducting a rapid thermal annealing (RTA) process at 100° C. for 10 seconds and implantation so as to activate Si. Using buffer hydrofluoric acid (BHF), dilute hydrofluoric acid (DHF) and ammonia (NH₄OH), the surface was subsequently cleaned, the Al₂O₃ film was removed and the surface was treated. Subsequently, Al₂O₃ was formed so as to have a thickness of 13 nm by an atomic layer deposition (ALD), and TaN was formed so as to have a thickness of 30 nm by an ion-beam sputter (IBS) method. In this way, the insulating material 730 and the intermediate layer 842 were formed.

Next, the TaN was etched through reactive ion etching using SF₆ as an etching gas, and the Al₂O₃ was etched through wet etching using BHF. As a result, an opening was formed in a region where the source electrode and the drain electrode were to be formed. After that, a multilayer film of titanium (Ti) and gold (Au) was formed by a deposition method, and the drain electrode and the source electrode (the input/output electrodes 250) were formed by a lift-off method. A multilayer film of titanium (Ti) and gold (Au) was further deposited and the conductive layer 244 was formed by a lift-off method. Subsequently, the TiN disposed other than the region under the conductive layer 244 was removed by performing a reactive ion etching using SF₆ as an etching gas, and the gate electrode was obtained.

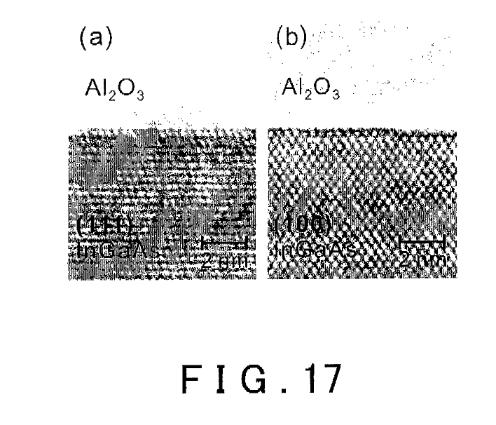

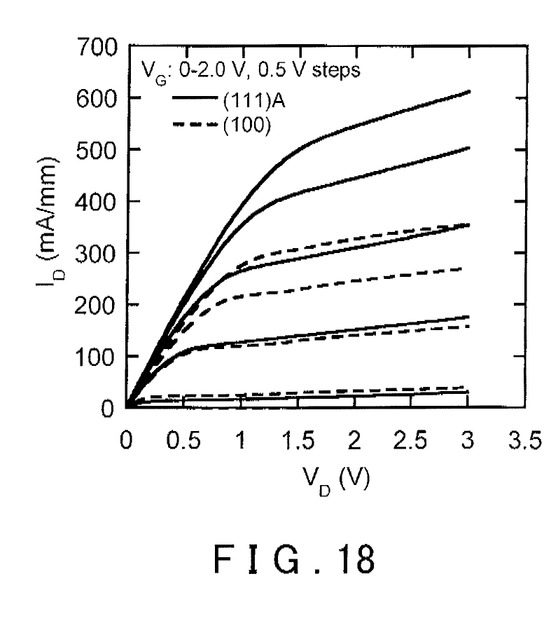

FIG. 17(a) is a TEM image of a boundary between InGaAs of the (111)A plane and Al₂O₃ formed by the ALD method. FIG. 17(b) is a TEM image of a boundary between InGaAs of the (100)A plane and Al₂O₃ formed by the ALD method. In both cases, the boundaries, which are clear at the atomic-layer level, were formed. FIG. 18 illustrates drain current-drain voltage characteristics of the fabricated field effect transistor. FIG. 18 shows data in which the gate voltage was changed from 0V to 2V by a step of 0.5 V. In the figure, the solid line represents the characteristics of the case where InGaAs was in the (111)A plane. The dashed line in the figure represents the characteristics of the case where InGaAs was in the (100) plane.

It was proven that larger current flows with the same voltage when InGaAs was in the (111)A plane compared to when InGaAs was in the (100) plane, in other words, the former case has fine I-V characteristics. In the case of InGaAs in the (111) plane, the threshold voltage was −0.22 V, and the S factor was 231 mV/dec. In the case of InGaAs in the (100) plane, the threshold voltage was +0.10 V, and the S factor was 136 mV/dec. The S factor represents a gate voltage required for shifting a value of the element current by a single digit, which is an indicative gate voltage necessary for on/off of the transistor.

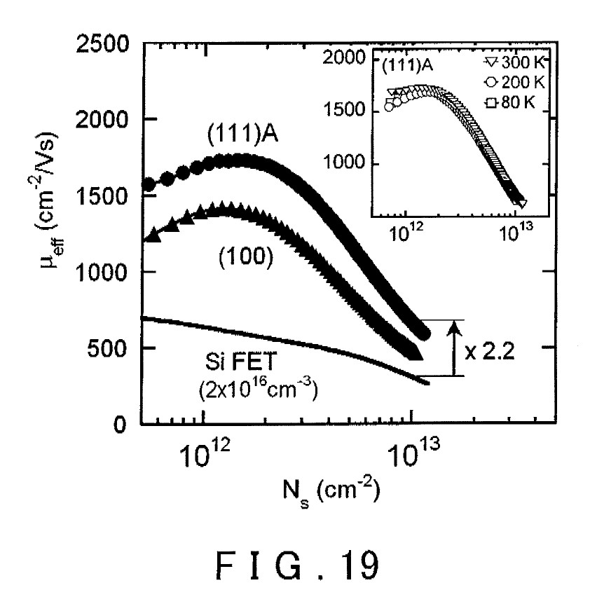

FIG. 19 is a graphic representation having the vertical axis that represents an effective mobility and the horizontal axis that represents a carrier density. In the figure, the circles represent the case where InGaAs was in the (111)A plane whereas the triangles represent the case where InGaAs was in the (100) plane. It was found that the mobility was large when InGaAs was in the (111)A plane compared to when InGaAs was in the (100) plane.

### <Exemplary Embodiment 4>

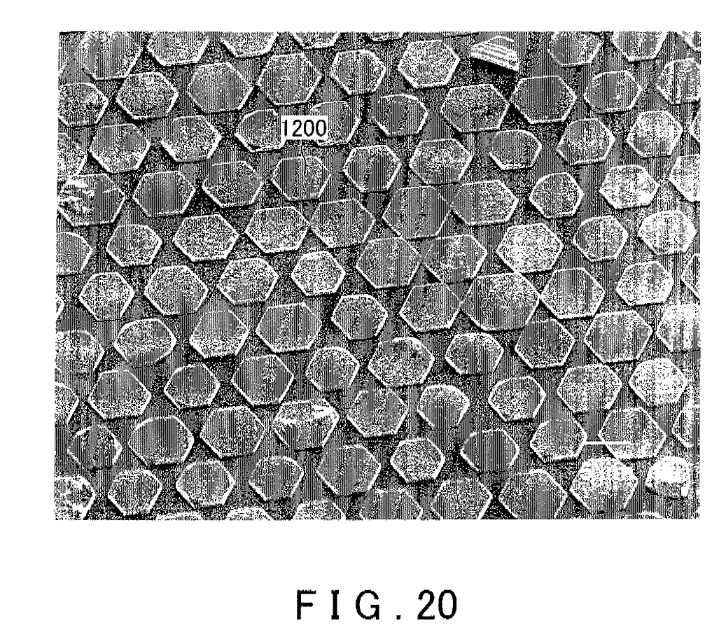

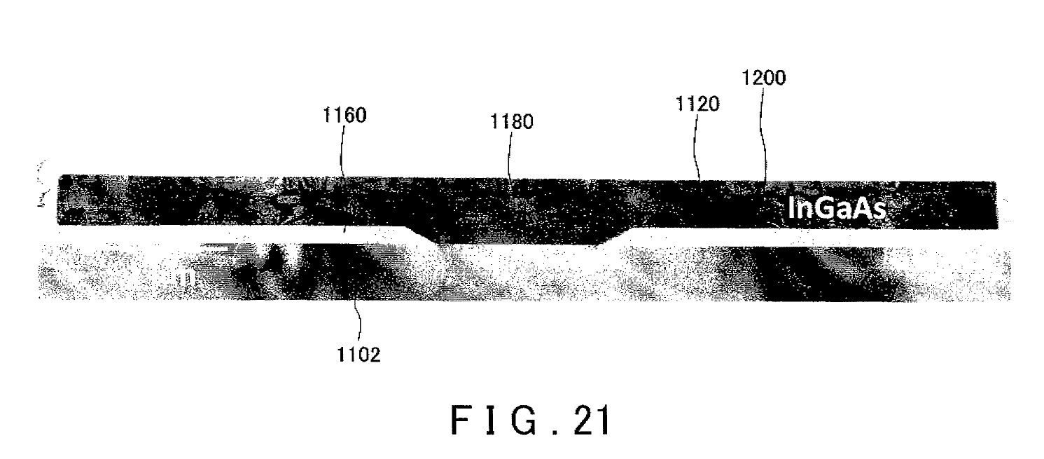

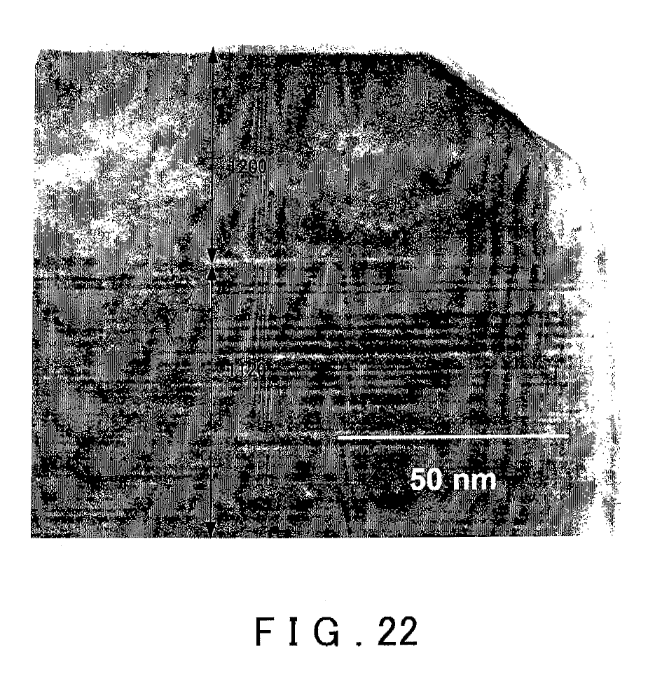

FIG. 20 is an SEM image of a plurality of pieces of upper-layer compound semiconductor 1200 whose crystals have been grown on an inhibition layer. The upper-layer compound semiconductor 1200 is a compound semiconductor layer which was obtained by further performing the epitaxial growth on the lateral compound semiconductor 1120 in the semiconductor device 1100 shown in FIG. 11. FIG. 21 is a TEM image of a piece of the upper-layer compound semiconductor 1200 of FIG. 20 showing its cross section. FIG. 22 is an enlarged TEM image of the cross section of FIG. 21 around the surface of the upper-layer compound semiconductor.

SiO₂ as the inhibition layer 1160 was formed on the Si base wafer 1102, and the opening 1162 was formed in the SiO₂. After a preprocessing, the seed compound semiconductor 1180 was grown inside the opening 1162 by conducting a selective epitaxial growth (a first growth), and the lateral compound semiconductor 1120 that serves as the inhibition layer 1160 was laterally grown on the SiO₂ (a second growth). The upper-layer compound semiconductor 1200 was further epitaxially grown on the lateral compound semiconductor 1120 (a third growth).

Conditions for the preprocessing, the first growth, the second growth and the third growth were as follows. The source gases used in each step were trimethyl-gallium (TMGa), trimethyl-indium (TMIn) and tertiary-butyl arsine (TBAs). The partial pressures of TMIn and TBAs in each step were 0.13 Pa and 5.4 Pa respectively. The processing temperature was 620° C. The processing time of the preprocessing was 5 minutes. The processing time of the first growth, the second growth and the third growth were 20 minutes respectively.

Moreover, the partial pressures of TMGa used in each step were different. The partial pressures of TMGa at the preprocessing, the first growth, the second growth and the third growth were 0 Pa, 0.16 Pa, 0.08 Pa and 0.24 Pa respectively. By changing the TMGa partial pressure in this way, crystal growths corresponding to the selective epitaxial growth in the opening (the first growth), the lateral growth (the second growth) and the additional selective epitaxial growth (the third growth) were realized.

It can be seen from FIG. 22 that the upper-layer compound semiconductor 1200 which was formed by the additional selective epitaxial growth has a highly-flat cross-section compared to that of the lateral compound semiconductor 1120 which was laterally grown, and therefore it can have better crystallinity.

The operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if a process flow is described using phrases such as “first” or “next” in the claims, embodiments, or diagrams, it does not necessarily mean that the process must be performed in this order.

### DESCRIPTION OF REFERENCE NUMERALS

110 semiconductor device, 120 compound semiconductor, 126 first main plane, 128 second main plane, 130 insulating material, 140 MIS-type electrode, 150 input/output electrodes, 210 semiconductor device, 220 compound semiconductor, 222 source regions, 224 drain region, 226 first main plane, 228 second main plane, 230 insulating material, 236 insulating material, 238 insulating material, 240 MIM-type electrode, 242 intermediate layer, 244 conductive layer, 250 input/output electrode, 360 sacrificial layer, 390 photomask, 392 opening, 422 region, 424 region, 730 insulating material, 842 intermediate layer, 930 insulating material, 936 insulating material, 938 insulating material, 942 intermediate layer, 946 intermediate layer, 948 intermediate layer, 1100 semiconductor device, 1102 base wafer, 1106 first main plane, 1108 second main plane, 1110 MISFET, 1120 lateral compound semiconductor, 1122 first lateral compound semiconductor, 1124 second lateral compound semiconductor, 1126 upper-layer compound semiconductor, 1130 insulating material, 1140 MIS-type electrode, 1150 input/output electrode, 1160 inhibition layer, 1162 opening, 1170 seed crystal, 1180 seed compound semiconductor, 1200 upper-layer compound semiconductor

1. A semiconductor device comprising:
a III-V Group compound semiconductor having a zinc-blende-type crystal structure;
an insulating material being in contact with the (111) plane of the III-V Group compound semiconductor, a plane of the III-V Group compound semiconductor equivalent to the (111) plane, or a plane that has an off angle with respect to the (111) plane or the plane equivalent to the (111) plane; and
an MIS-type electrode being in contact with the insulating material and including a metal conductive material.

2. The semiconductor device according to claim 1, wherein
the insulating material is in contact with the (111)A plane of the III-V Group compound semiconductor, a plane of the III-V Group compound semiconductor equivalent to the (111)A plane, or a plane having an off angle with respect to the (111)A plane or the plane equivalent to the (111)A plane.

3. The semiconductor device according to claim 1, comprising
an MIS-type field effect transistor comprising the III-V Group compound semiconductor, the insulating material, the MIS-type electrode and a pair of input/output electrodes electrically connected to the III-V Group compound semiconductor.

4. The semiconductor device according to claim 3, wherein
a channel layer of the MIS-type field effect transistor comprises In_{z}Ga_{1-z}As_{z′}Sb_{1-z′} (where 0≦z≦1, 0≦z′≦1) or InₓGa₁₋ₓAs_{y}P_{1-y} (where 0≦x≦1, 0≦y≦1).

5. The semiconductor device according to claim 1, wherein
the III-V Group compound semiconductor comprises an N-type semiconductor.

6. The semiconductor device according to claim 1, wherein
the III-V Group compound semiconductor comprises a P-type semiconductor.

7. The semiconductor device according to claim 1, wherein
the insulating material comprises at least one member selected from the group consisting of Al₂O₃, Ga₂O₃, La₂O₃, AlN, GaN, SiO₂, ZrO₂, HfO₂, HfₓSi₁₋ₓO_{y} (where 0≦x≦1, 1≦y≦2), HfₓAl₂₋ₓO_{y} (where 0≦x≦2, 1≦y≦3), Hf_{x′}Si_{1-x′}O_{y′}N_{2-y′} (where 0≦x′≦1, 1≦y′≦2) and Ga_{2-x″}Gd_{x″}O₃ (where 0≦x″≦2), or a layered structure thereof.

8. The semiconductor device according to claim 1, wherein
the insulating material comprises a III-V Group compound semiconductor containing Al and having a zinc-blende-type crystal structure, or an oxide of a III-V Group compound semiconductor containing Al and having a zinc-blende-type crystal structure.

9. The semiconductor device according to claim 1, wherein
the metal conductive material comprises at least one member selected from the group consisting of TaC, TaN, TiN, Ti, Au, W, Pt and Pd.

10. The semiconductor device according to claim 1, further comprising:
a base wafer selected from the group consisting of a Si wafer, an SOI wafer and a GOI wafer,
wherein the III-V Group compound semiconductor is disposed on a part of the base wafer.

11. A method of producing a semiconductor device, the method comprising:
a step of preparing a III-V Group compound semiconductor that has a zinc-blende-type crystal structure and that has the (111) plane, a plane equivalent to the (111) plane, or a plane having an off angle with respect to the (111) plane or the plane equivalent to the (111) plane;
a step of forming an insulating material that is in contact with the (111) plane, the plane equivalent to the (111) plane, or the plane having an off angle with respect to the (111) plane or the plane equivalent to the (111) plane; and
a step of forming an MIS-type electrode that is in contact with the insulating material and that is made of a metal conductive material.

12. The method of producing a semiconductor device according to claim 11, wherein
the insulating material is in contact with the (111)A plane of the III-V Group compound semiconductor, a plane of the III-V Group compound semiconductor equivalent to the (111)A plane, or a plane having an off angle with respect to the (111)A plane or the plane equivalent to the (111)A plane.

13. The method of producing a semiconductor device according to claim 11, further comprising:
a step of forming input/output electrodes electrically connected to the III-V Group compound semiconductor.

14. The method of producing a semiconductor device according to claim 13, wherein
the step of forming an MIS-type electrode is performed before the step of forming the input/output electrodes.

15. The method of producing a semiconductor device according to claim 13, wherein
the step of forming input/output electrodes is performed before the step of forming an insulating material.

16. The method of producing a semiconductor device according to claim 11, wherein
the insulating material is formed and obtained by an ALD method or a MOCVD method under an atmosphere containing a reducing material.

17. The method of producing a semiconductor device according to claim 15, further comprising
a step of annealing the insulating material under vacuum or under an atmosphere containing hydrogen after the insulating material is formed.

18. The method of producing a semiconductor device according to claim 11, wherein
the step of preparing a III-V Group compound semiconductor comprises:
a step of preparing any one wafer of a Si wafer, an SOI wafer and a GOI wafer; and
a step of forming the III-V Group compound semiconductor on a part of the wafer.

19. A semiconductor wafer in which
a III-V Group compound semiconductor having a zinc-blende-type crystal structure has been placed, wherein the (111) plane of the III-V Group compound semiconductor, a plane of the III-V Group compound semiconductor equivalent to the (111) plane, or a plane having an off angle with respect to the (111) plane or the plane equivalent to the (111) plane has been disposed in parallel to the main plane of the semiconductor wafer.

20. The semiconductor wafer according to claim 19, wherein
the (111)A plane of the III-V Group compound semiconductor, a plane of the III-V Group compound semiconductor equivalent to the (111)A plane, or a plane having an off angle with respect to the (111)A plane or the plane equivalent to the (111)A plane has been disposed in parallel to the main plane of the semiconductor wafer.

21. The semiconductor wafer according to claim 19, wherein
the III-V Group compound semiconductor comprises In_{z}Ga_{1-z}As_{z′}Sb_{1-z′} (where 0≦z≦1, 0≦z′≦1) or InₓGa₁₋ₓAs_{y}P_{1-y} (where 0≦x≦1, 0≦y≦1).

22. The semiconductor wafer according to claim 19, further comprising
any one wafer of a Si wafer, an SOI wafer and a GOI wafer, wherein the III-V Group compound semiconductor has been disposed on a part of the wafer.

23. The semiconductor wafer according to claim 22, further comprising
an inhibition layer that inhibits crystal growth of the III-V Group compound semiconductor that occurs on a surface of a Si or Ge crystal layer of a surface of the wafer, wherein an opening penetrating the inhibition layer to the Si or Ge crystal layer has been formed in the inhibition layer, and the III-V Group compound semiconductor has been formed inside the opening.

24. The semiconductor wafer according to claim 23, wherein the III-V Group compound semiconductor comprises:
a seed compound semiconductor whose crystal has grown to have a convex shape protruding from a surface of the inhibition layer; and
a lateral compound semiconductor having laterally grown along the inhibition layer with the seed compound semiconductor serving as a nucleus.

25. The semiconductor wafer according to claim 24, wherein the lateral compound semiconductor comprises:
a first lateral compound semiconductor having laterally grown along the inhibition layer with the seed compound semiconductor serving as a nucleus; and
a second lateral compound semiconductor whose crystal has laterally grown along the inhibition layer in a direction different from that of the first lateral compound semiconductor using the first lateral compound semiconductor as a nucleus.

26. The semiconductor wafer according to claim 24, wherein the III-V Group compound semiconductor further comprises an upper-layer compound semiconductor whose crystal has grown on the lateral compound semiconductor.

27. A semiconductor wafer comprising:
a III-V Group compound semiconductor having a zinc-blende-type crystal structure; and
an insulating material being in contact with the (111) plane of the III-V Group compound semiconductor, a plane of the III-V Group compound semiconductor equivalent to the (111) plane, or a plane having an off angle with respect to the (111) plane or the plane equivalent to the (111) plane.

28. The semiconductor wafer according to claim 27, wherein
the insulating material being in contact with the (111)A plane of the III-V Group compound semiconductor, a plane of the III-V Group compound semiconductor equivalent to the (111)A plane, or a plane having an off angle with respect to the (111)A plane or the plane equivalent to the (111)A plane.

29. The semiconductor wafer according to claim 27, wherein
the III-V Group compound semiconductor comprises In_{z}Ga_{1-z}As_{z′}Sb_{1-z′} (where 0≦z≦1, 0≦z′≦1) or InₓGa₁₋ₓAs_{y}P_{1-y} (where 0≦x≦1, 0≦y≦1).

30. The semiconductor wafer according to claim 27, further comprising:
any one wafer of a Si wafer, an SOI wafer and a GOI wafer, wherein the III-V Group compound semiconductor has been disposed on a part of the wafer.

31. The semiconductor wafer according to claim 27, wherein
the insulating material comprises at least one member selected from the group consisting of Al₂O₃, Ga₂O₃, La₂O₃, AlN, GaN, SiO₂, ZrO₂, HfO₂, HfₓSi₁₋ₓO_{y} (where 0≦x≦1, 1≦y≦2), HfₓAl₂₋ₓO_{y} (where 0≦x≦2, 1≦y≦3), Hf_{x′}Si_{1-x′}O_{y′}N_{2-y′} (where 0≦x′≦1, 1≦y′≦2) and Ga_{2-x″}Gd_{x″}O₃ (where 0≦x″≦2), or a layered structure thereof.

32. The semiconductor wafer according to claim 27, wherein
the insulating material comprises a III-V Group compound semiconductor containing Al and having a zinc-blende-type crystal structure, or an oxide of a III-V Group compound semiconductor containing Al and having a zinc-blende-type crystal structure.

33. A method of producing a semiconductor wafer comprising a III-V Group compound semiconductor, the method comprising:
a step of preparing a base wafer;
a step of forming, on the base wafer, an inhibition layer that inhibits crystal growth of the III-V Group compound semiconductor;
a step of forming, in the inhibition layer, an opening penetrating the inhibition layer to the base wafer;
a step of growing, in the opening, a crystal of a seed compound semiconductor to make it have a convex shape protruding from a surface of the inhibition layer;
a step of growing a crystal of a lateral compound semiconductor along the inhibition layer with the seed compound semiconductor serving as a nucleus; and
a step of growing a crystal of an upper-layer compound semiconductor on the lateral compound semiconductor.
